(19) United States
(12) Patent Application Publication
(10) Pub. No.: US 2019/0292418 A1
(43) Pub. Date: Sep. 26, 2019

(54) ELECTRICALLY CONDUCTIVE ADHESIVES

(71) Applicant: E I DU PONT DE NEMOURS AND COMPANY, Wilmington, DE (US)

(72) Inventors: Fei Xiang, Shanghai (CN); Jose Manuel Rodriguez-Parada, Hockessin, DE (US); Lida Qiu, Shanghai (CN)

(21) Appl. No.: 16/317,608

(22) PCT Filed: Jun. 27, 2017
(86) PCT No.: PCT/US17/39475

§ 371 Date: Jan. 14, 2019

(30) Foreign Application Priority Data
Jul. 15, 2016 (CN) 201610555459.7
Nov. 29, 2016 (CN) 201611070470.0

(51) Int. Cl. C09J 9/02; H01L 31/05; H01L 31/02; C09J 127/20

(52) U.S. Cl. CPC C09J 9/02; H01L 31/0512; H01L 31/0445; C09J 127/20; H01L 31/02008

(57) ABSTRACT

Disclosed herein are electrically conductive adhesive compositions and their use in solar cell modules, wherein the electrically conductive adhesives comprise one or more olefinic carboxylic acids or derivatives thereof.

### TECHNICAL FIELD

The disclosure is related to electrically conductive adhesives (ECA) comprising olefinic carboxylic acid or derivatives thereof.

### BACKGROUND

In solar cell modules, the solar cells have surface electrodes, to which the wiring members (also called electro-conductive interconnect members or ribbons) are connected for extracting power from the cells. The wiring members are usually in the form of metal strips (such as Cu strips) and they are often connected to the surface electrodes by soldering. However, since relatively high temperatures are necessary for such soldering, stresses are applied to the connect structure due to the difference in co-efficiency of thermal shrinkage among the semiconductor structure responsible for power generation, the surface electrodes, the solder, and the wiring members. Such thermal stresses can cause the solar cell to be warped and cracked.

To solve this problem, people have proposed the use of polymer-based electrically conductive adhesives in place of solder to connect the wiring members with the surface electrodes of the solar cells. Such polymer-based electrically conductive adhesives typically are comprised of insulating polymers (such as, epoxy resins, acrylic polymers, phenoxy resins, polyimides, or silicone rubbers) and electro-conductive particles (such as Ag particles), see, for example, U.S. Patent Publication Nos. 2010/0147355 and 2012/0012153. There also have been disclosures of rubber-based or ethylene copolymer-based (such as those based on ethylene vinyl acetate (EVA)) electrically conductive adhesives. However, there is still a need to develop novel polymer-based electrically conductive adhesives with further improved bonding strength to the surface electrodes of the solar cells.

### SUMMARY

The purpose of the present disclosure is to provide an electrically conductive adhesive composition comprising: a) a binder formed of or comprising at least one peroxide curable elastomer and at least one peroxide-based curing agent; b) 40-93 wt % of conductive particles dispersed in the binder; and c) 0.1-1.5 wt % of olefinic carboxylic acid or derivative thereof dispersed in the binder, with the wt % of all components comprised in the composition totaling to 100 wt %, and wherein, the olefinic carboxylic acid has a formula R¹CO₂R², R¹ being hydrocarbyl or substituted hydrocarbyl having 4 or more carbon atoms, and containing one α-olefinic double bond, provided that the double bond is not part of a ring; and R² being hydrogen, hydrocarbyl, or substituted hydrocarbyl.

In one embodiment of the electrically conductive adhesive composition, the at least one peroxide-based curing agent is present in the binder at a level of 0.1-20 wt %, or 0.5-10 wt %, or 1-5 wt % and the at least one peroxide-based curing agent is selected from the group consisting of 1,1-bis(tert-buty peroxy)-3,3,5-trimethylcyclohexane; 1,1-di(tert-butylperoxy)cyclohexane; 2,5-di(tert-butylperoxy)-2,5-dimethyl-3-hexyne; 2,5-bis(tert-butylperoxy)-2,5-dimethylhexane; tert-Butylperoxy 2-ethylhexyl carbonate; dicumyl peroxide; benzoyl peroxide; acetylacetone peroxide; methyl isobutyl ketone peroxide; dibenzoyl peroxide; cyclohexanone peroxide; di(4-tert-butylcyclohexyl) peroxydicarbonate; and combinations of two or more thereof.

In a further embodiment of the electrically conductive adhesive composition, the at least one peroxide curable elastomer is a selected from the group consisting of fluoroelastomers, ethylene/alkyl (meth)acrylate copolymer elastomers, and combinations of two or more thereof.

In a yet further embodiment of the electrically conductive adhesive composition, the binder is present at a level of 7-60 wt %, or 15-60 wt %, or 17-55 wt %, based on the total weight of the electrically conductive adhesive composition.

In a yet further embodiment of the electrically conductive adhesive composition, the conductive particles are present at a level of 40-85 wt % or 45-83 wt %, based on the total weight of the electrically conductive adhesive composition, and wherein, the conductive particles are selected from the group consisting of Au, Ag, Ni, Cu, Al, Sn, Zn, Ti, Sn, Bi, W, Pb, and alloys of two or more thereof, or, the conductive particles are Ag flakes.

In a yet further embodiment of the electrically conductive adhesive composition, the olefinic carboxylic acid or derivative thereof is present at a level of 0.2-1.5 wt % or 0.5-1 wt %, based on the total weight of the electrically conductive adhesive composition.

In a yet further embodiment of the electrically conductive adhesive composition, the olefinic carboxylic acid or derivative thereof is selected from the group consisting of 4-pentenoic acid; 2-methyl-4-pentenoic acid methyl ester; 2,2-dimethyl-4-pentenoic acid; 5-hexenoic acid; 6-heptenoic acid; 6-heptenoic acid methyl ester; 7-octenoic acid; 8-nonenoic acid; 9-decenoic acid; 10-undecenoic acid; mono-2-(methacryloyloxy)ethyl succinate; methyl 10-undecenoate; 11-dodecenoic acid; 7-oxo-11-dodecenoic acid; 12-tridecanoic acid; and combinations of two or more thereof.

Further provided herein is a film or sheet formed of the electrically conductive adhesive composition described above.

Yet further provided herein is an electrically conductive adhesive prepared from the electrically conductive adhesive composition as described above, wherein, the at least one peroxide curable elastomer is cured by the at least one peroxide-based curing agent.

Yet further provided herein is a solar cell module comprising at least one solar cell and at least one wiring member, wherein, the at least one solar cell has at least one surface electrode and the at least one wiring member is connected to the at least one surface electrode via the electrically conductive adhesive described above.

In one embodiment of the solar cell module, the at least one solar cell has a front surface electrode and a back surface electrode, and wherein there are one or more front wiring members connected to the front surface electrode via the electrically conductive adhesive and one or more back wiring members connected to the back surface electrode via the electrically conductive adhesive.

In a further embodiment of the solar cell module, the at least one solar cell is a wafer-based solar cell.

In a yet further embodiment of the solar cell module, the at least one solar cell is a thin film solar cell.

Yet further provided herein is a solar cell module comprising one or more strings of solar cells, wherein each string of solar cells comprise at least a first solar cell and a second solar cell, with i) each of the first and second solar cells comprising a front surface electrode and a back surface electrode; ii) the first and second solar cells being positioned with an edge of the back surface of the second solar cell overlapping an edge of the front surface of the first solar cell; and iii) a portion of the front surface electrode of the first solar cell being hidden by the second solar cell and bonded to a portion of the back surface electrode of the second solar cell with the electrically conductive adhesive described above to electrically connect the first and second solar cells in series.

In accordance with the present disclosure, when a range is given with two particular end points, it is understood that the range includes any value that is within the two particular end points and any value that is equal to or about equal to any of the two end points.

### DETAILED DESCRIPTION

Disclosed herein are electrically conductive adhesive (ECA) compositions that comprise: a) a binder formed of or comprising at least one peroxide curable elastomer and at least one peroxide-based curing agent, b) conductive particles, and c) at least one olefinic carboxylic acid or derivative thereof.

Peroxide curable elastomers include both saturated and unsaturated elastomers and the basic chemistry of peroxide decomposition and subsequent crosslink-forming reactions is well established. In general, at the beginning of the curing process, the organic peroxide splits into 2 free radicals, according to the equation:

RO:OR→2RO.

The free radicals formed as a consequence of the decomposition of the peroxide, abstract hydrogen atoms from the elastomer macromolecules, converting them into macroradicals:

˜CH₂C(CH₃)=CHCH₂˜+RO.→ROH+˜CH₂C(CH₃)═CHHC.˜

The resulting macroradicals react with each other by forming C—C intermolecular bridges:

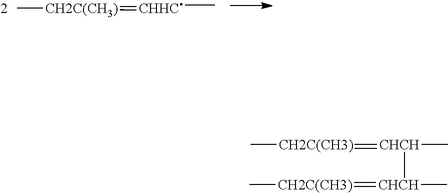

Suitable peroxide curable elastomers include, without limitation, fluroelastomers, ethylene/alkyl (meth)acrylate copolymer elastomers (AEM rubbers), ethylene vinyl acetate (EVA), silicones (including fluorosilicones), cyanoacrylates, nitrile butadiene rubbers (NBR), hydrogenated nitrile butadiene rubbers (HNBR), neoprene rubbers, ethylene propylene diene monomer (M-class) rubbers (EPDM rubbers), etc.

In one embodiment, the peroxide curable elastomers used herein are fluoroelastomers containing the following cure site monomers, i) bromine-containing olefins; ii) iodine-containing olefins; iii) bromine-containing vinyl ethers; iv) iodine-containing vinyl ethers; v) 1,1,3,3,3-pentafluoropropene (2-HPFP); and vi) non-conjugated dienes.

Examples of bromine-containing olefins are CF₂═CFOCF₂CF₂CF₂OCF₂CF₂Br; bromotrifluoroethylene; 4-bromo-3,3,4,4-tetrafluorobutene-1 (BTFB); etc. Exemplary bromine-containing olefins also include other vinyl bromide, such as, 1-bromo-2,2-difluoroethylene; perfluoroallyl bromide; 4-bromo-1,1,2-trifluorobutene-1; 4-bromo-1,1,3,3,4,4,-hexafluorobutene; 4-bromo-3-chloro-1,1,3,4,4-pentafluorobutene; 6-bromo-5,5,6,6-tetrafluorohexene; 4-bromoperfluorobutene-1; and 3,3-difluoroallyl bromide.

Iodine-containing olefins are those having the following formula: CHR═CH—Z—CH₂CHR—I, wherein R is —H or —CH₃ and Z is a C₁-C₁₈ (per)fluoroalkylene radical, linear or branched, optionally containing one or more ether oxygen atoms, or a (per)fluoropolyoxyalkylene radical as disclosed in U.S. Pat. No. 5,674,959. Other examples of useful iodine-containing olefins are unsaturated ethers of the following formula: I(CH₂CF₂CF₂)ₙOCF═CF₂; ICH₂CF₂O[CF(CF₃)CF₂O]ₙCF═CF₂; and the like, wherein n is an integer of 1-3, such as disclosed in U.S. Pat. No. 5,717,036.

Bromine-containing vinyl ethers useful herein include 2-bromo-perfluoroethyl perfluorovinyl ether and fluorinated compounds of the class CF₂Br—R_{f}—O—CF═CF₂ (R_{f} is a perfluoroalkylene group), such as CF₂BrCF₂O—CF═CF₂, and fluorovinyl ethers of the class ROCF═CFBr or ROCBr═CF₂ (where R is a lower alkyl group or fluoroalkyl group) such as CH₃OCF═CFBr or CF₃CH₂OCF═CFBr.

Iodine-containing vinyl ethers include iodoethylene; 4-iodo-3,3,4,4-tetrafluorobutene-1 (ITFB); 3-chloro-4-iodo-3,4,4-trifluorobutene; 2-iodo-1,1,2,2-tetrafluoro-1-(vinyloxy)ethane; 2-iodo-1-(perfluorovinyloxy)-, 1,-2,2-tetrafluoroethylene; 1,1,2,3,3,3-hexafluoro-2-iodo-1-(perfluorovinyloxy)propane; 2-iodoethyl vinyl ether; 3,3,4,5,5,5-hexafluoro-4-iodopentene; and iodotrifluoroethylene, which are disclosed in U.S. Pat. No. 4,694,045. Allyl iodide and 2-iodo-perfluoroethyl perfluorovinyl ether are also useful herein.

Non-conjugated diene cure site monomers include, but are not limited to 1,4-pentadiene; 1,5-hexadiene; 1,7-octadiene; 3,3,4,4-tetrafluoro-1,5-hexadiene; and others, such as those disclosed in Canadian Patent 2,067,891 and European Patent 0784064A1. A suitable triene is 8-methyl-4-ethylidene-1,7-octadiene. Of the cure site monomers listed above, preferred compounds, include 4-bromo-3,3,4,4-tetrafluorobutene-1 (BTFB); 4-iodo-3,3,4,4-tetrafluorobutene-1 (ITFB); allyl iodide; and bromotrifluoroethylene.

Additionally, iodine-containing end groups, bromine-containing end groups or mixtures thereof may optionally be present at one or both of the fluoroelastomer polymer chain ends as a result of the use of chain transfer or molecular weight regulating agents during preparation of the fluoroelastomers. The amount of chain transfer agent, when employed, is calculated to result in an iodine or bromine level in the fluoroelastomer in the range of about 0.005-5 wt %, or about 0.05-3 wt %.

Examples of chain transfer agents include iodine-containing compounds that result in incorporation of bound iodine at one or both ends of the polymer molecules. Methylene iodide; 1,4-diiodoperfluoro-n-butane; and 1,6-diiodo-3,3,4,4,tetrafluorohexane are representative of such chain transfer agents. Other iodinated chain transfer agents include 1,3-diiodoperfluoropropane; 1,6-diiodoperfluorohexane; 1,3-diiodo-2-chloroperfluoropropane; 1,2-di(iododifluoromethyl)-perfluorocyclobutane; monoiodoperfluoroethane; monoiodoperfluorobutane; 2-iodo-1-hydroperfluoroethane, etc. Also included are the cyano-iodine chain transfer agents disclosed in European Patent 0868447A1. Particularly preferred are diiodinated chain transfer agents. Examples of brominated chain transfer agents include 1-bromo-2-iodoperfluoroethane; 1-bromo-3-iodoperfluoropropane; 1-iodo-2-bromo-1,1-difluoroethane and others such as disclosed in U.S. Pat. No. 5,151,492.

Other chain transfer agents suitable for use in the fluoroelastomers used herein include those disclosed in U.S. Pat. No. 3,707,529. Examples of such chain transfer agents include isopropanol, diethylmalonate, ethyl acetate, carbon tetrachloride, acetone, and dodecyl mercaptan.

Units of cure site monomer are typically present at a level of about 0.05-10 wt %, or about 0.05-5 wt %, or about 0.05-3 wt %, based on the total weight of fluoroelastomer used herein.

Specific fluoroelastomers which may be used herein include, without limitation, those fluoroelastomers having at least about 53 wt % fluorine and comprising copolymerized units of i) vinylidene fluoride and hexafluoropropylene; ii) vinylidene fluoride, hexafluoropropylene, and tetrafluoroethylene; iii) vinylidene fluoride, hexafluoropropylene, tetrafluoroethylene, and 4-bromo-3,3,4,4-tetrafluorobutene-1; iv) vinylidene fluoride, hexafluoropropylene, tetrafluoroethylene, and 4-iodo-3,3,4,4-tetrafluorobutene-1; v) vinylidene fluoride, perfluoro(methyl vinyl) ether, tetrafluoroethylene, and 4-bromo-3,3,4,4-tetrafluorobutene-1; vi) vinylidene fluoride, peril uoro(methyl vinyl) ether, tetrafluoroethylene, and 4-iodo-3,3,4,4-tetrafluorobutene-1; or vii) vinylidene fluoride, peril uoro(methyl vinyl) ether, tetrafluoroethylene, and 1,1,3,3,3-pentafluoropropene.

The fluoroelastomers used herein are typically prepared in an emulsion polymerization process, which may be a continuous, semi-batch, or batch process.

The fluoroelastomers useful herein are also commercially available from various vendors. For example, suitable fluoroelastomers may be obtained from E.I. du Pont de Nemours and Company (U.S.A.) (hereafter “DuPont”) under the trade names Viton®GF-S; Viton®GAL-S; Viton®GBL-S; Viton®GBL; Viton®GLT-S; Viton®GBLT-S; Viton®GFLT-S; Viton®ETP-S; or from 3M (U.S.A.) under the trade names 3M™Dyneon™FLS 2650; Dyneon™2260; Dyneon™FPO3740; Dyneon™FPO3741; or from Daikin Industries, Ltd. (Japan) under the trade names DAI-EL™ 801; DAI-EL™ 802; DAI-EL™ 8002; DAI-EL™ 901; DAI-EL™ 952; DAI-EL™ LT252; DAI-EL™ LT303L; or from Tetralene Elastomer, Inc. (U.S.A.) under the trade name FluoTrex™.

In a further embodiment, the peroxide curable elastomers are ethylene/alkyl (meth)acrylate copolymer elastomers, also known as AEM rubbers. AEM rubbers are derived from copolymerization of polymerized units of ethylene and about 45-90 wt %, or about 50-80 wt %, or about 50-75 wt % of polymerized units of at least one alkyl (meth)acrylate. The term “(meth)acrylate” is used herein to refer to esters of methacrylic acids and/or esters of acrylic acids, and the term “meth” is used herein to refer to —H or branched or non-branched groups C₁-C₁₀ alkyl, and the term “alkyl” is used herein to refer to —H or branched or non-branched groups of C₁-C₁₂ alkyl, C₁-C₂₀ alkoxyalkyl, C₁-C₁₂ cyanoalkyl, or C₁-C₁₂ fluoroalkyl. The alkyl (meth)acrylate groups used herein include, without limitation, alkyl acrylate, alkyl methacrylates, alkyl ethacrylates, alkyl propacrylates, alkyl hexacrylates, alkoxyalkyl methacrylates, alkoxyalkyl ethacryates, alkoxyalkyl propacrylates and alkoxyalkyl hexacrylates. The alkyl groups may be substituted with cyano groups or one or more fluorine atoms. That is, the alkyl group may be a C₁-C₁₂ cyanoalkyl group or a C₁-C₁₂ fluoroalkyl group. The AEM rubbers may also comprise copolymerized units of more than one species of the alkyl (meth)acrylates, for example two different alkyl acrylate monomers. For example, the ethylene/alkyl (meth)acrylate copolymers used herein include, without limitation, ethylene/methyl acrylate copolymers (EMA), ethylene/ethyl acrylate copolymers (EEA), and ethylene/butyl acrylate copolymers (EBA).

Moreover, the AEM rubbers used herein may optionally further comprise up to about 5 wt % of a functionalized comonomer, based on the total weight of the AEM rubbers. The optional functionalized comonomers used herein, include, without limitation, (meth)acrylate glycidyl esters (such as glycidyl methacrylate), chlorovinyl ether, maleic acids, and other comonomers having one or more reactive groups including acid, hydroxyl, anhydride, epoxy, isocyanates, amine, oxazoline, chloroacetate, carboxylic ester moieties, or diene functionality. Also conceivable is that the AEM rubbers used herein are made by copolymerizing ethylene and more than one (e.g., two) alkyl (meth)acrylate monomers. Examples are AEM rubbers made by polymerizing ethylene, methyl acrylate, and a second acrylate (such as butyl acrylate).

The AEM rubbers may be prepared by various processes well known in the polymer art. For example, the copolymerization can be run as a continuous process in an autoclave reactor. Or alternatively, the AEM rubbers used herein may be produced at high pressure and elevated temperature in a tubular reactor or the like. They can be separated from the product mixture with the un-reacted monomers and solvent (if used) by conventional means, e.g., vaporizing the non-polymerized materials and solvent under reduced pressure and at an elevated temperature.

The AEM rubbers used herein are also available commercially. Exemplary AEM rubbers may include those available from DuPont under the trade name Vamac®DP.

In a yet further embodiment, the peroxide curable elastomers used herein are ethylene/vinyl copolymers (EVA), derived from copolymerization of polymerized units of ethylene and about 5-50 wt %, or about 15-45 wt %, or about 20-45 wt % of copolymerized units of vinyl acetates, based on the total weight of the EVA. In accordance with the present disclosure, the EVA used herein may also comprise up to about 35 wt %, or up to about 25 wt %, or up to about 20 wt % of copolymerized units of one or more additional monomers. Such one or more additional comonomers may include, without limitation, (meth)acrylic acid, maleic anhydride, butyl acrylate, carbon monoxide, and combinations of two or more thereof. Suitable EVA also may be obtained commercially. For example, Elvax® EVA resins available from DuPont; Evatane™ EVA copolymers available from Arkerma, Inc. (France); Escorene™ EVA resins available from ExxonMobil Chemical (U.S.A.); Evaflex® EVA resins available from DuPont-Mitsui Polychemicals Co. Ltd. (Japan); or Ateva™ EVA resins available from Celanese (Canada) may be used herein.

In a yet further embodiment, the peroxide curable elastomers used herein are silicones having a general forming unit RₓSiO_{[(4-x)/2]}, wherein R is identical or different and is an unsubstituted or substituted hydrocarbon radical and x is a number that is >0 and less or equal to 3 or preferably from 1.9 to 2.1.

Suitable silicones include, without limitation, those commercially available from Dow Chemicals (U.S.A.) under the trade names, Dow Corning™C6-235; Dow Corning™C6-250; Dow Corning™C6-265; Silastic™HCM 60-1225 GRAY; Silastic™Q7-4535; Silastic™Q7-4565; and Toray DY 32-315 U, or from Wacker Chemical AG (Germany) under the trade names, Cenusil™R 340; Cenusil™R 350; Elastosil™ B 242; Elastosil™ B 227M; Elastosil™ C 713; Elastosil™ C 1451; Elastosil™ R 770/50; Elastosil™ R 752/70; Elastosil™ R Plus4806/20; Elastosil™ R Plus4110/70; Powersil™ 460; Powersil™ 3100 MH; Silpuran™ 8060/40; Silpuran™8030/40; etc.

The silicones used herein also may include fluorosilicones, which contain a silicone polymer chain with fluorinated side-chains. Suitable fluorosilicones include, without limitation, those commercially available from Dow Chemicals under the trade names, Silastic™LS5-8740; Dow Corning Toray™ DY 37-016U; Dow Corning Toray™ DY 37-029U; Dow Corning Toray™ LS 63U; Silastic™EFX70MHR00 Blue 5002; Silastic™FL 30-9201; Dow Corning Toray™ SE 1561 U; Dow Corning Toray™ SE 1570U; Xiameter™RBB-2220-55, or from Wacker under the trade names, Elastosil™FLR; Semicosil™927; Semicosil™992 JC; or from Specialty Silicone Products, Inc. (U.S.A.) under the trade names SSP-083; SSP-100; etc.

Cyanoacrylates used herein are polymers containing monomers with the following formula: H₂C═C(CN)—COOR, wherein, R is selected from C₁₋₁₅ alkyl, C₂₋₁₅ alkoxyalkyl, C₃₋₁₅ cycloalkyl, C₂₋₁₅ alkenyl, C₇₋₁₅ aralkyl, C₆₋₁₅ aryl, C₃₋₁₅ allyl and C₁₋₁₅ haloalkyl groups. Desirably, the monomer is selected from methyl cyanoacrylate, ethyl-2-cyanoacrylate, propyl cyanoacrylates, butyl cyanoacrylates (such as n-butyl-2-cyanoacrylate), octyl cyanoacrylates, allyl cyanoacrylate, 3-methoxyethyl cyanoacrylate and combinations thereof. A particularly desirable one is ethyl-2-cyanoacrylate. Suitable cyanoacrylates may be obtained commercially from Henkel (Germany) under the trade names Loctite™ 4902™; Loctite™ 3092™; etc.

Nitrile butadiene rubber (NBR) is a family of unsaturated copolymers of 2-propenenitrile and one or both of 1,2-butadiene and 1,3-butadiene.

Suitable NBR may be obtained from Nantex Industry Co., Ltd. (Taiwan) under the trade name, NANCAR™NBR, from JSR Corporation (Japan) under the product names, JSR N220S; JSR 240S; etc., from Synthos S.A. (Poland) under the product name KER, from LG Chem (Korea) under the product names, NBR7150; NBR3250; etc., or from Kumho Petrochemical (Korea) under the product names, KNB35L; KNB40M; etc.

Hydrogenated nitrile butadiene rubber (HNBR) is prepared via selective hydrogenation of butadiene groups and other unsaturated groups contained in a NBR. It is also understood that the HNBR used herein contains less than 40 double bounds per 1000 carbon atoms.

HNBR also are commercially available from Zeon Company (Japan) under the trade names, Zetpol®ZP-0020; Zetpol®ZP-2010; Zetpol®ZP4300; etc., or from LANXESS under the trade names, Therban®3406; Therban®4367; Therban®AT3404; and etc.

In a yet further embodiment, the peroxide curable elastomers used herein may be neoprene rubbers, a family of synthetic rubbers that are produced by polymerization of chloroprene monomers (CH₂═CCl—CH═CH₂). Suitable neoprene rubbers may be obtained from Denka Company Limited (Japan) under product name, Denka Chloroprene, or from Tosoh Corporation (Japan) under the trade names, Skyprene™ G-70; Skyprene™ B-30S; Skyprene™ Y-30S; etc., or from Shanna Synthetic Rubber Co., Ltd. (China) under the product name, SN 322, or from Lanxess Corporation (U.S.A.) under the trade name, Baypren™.

In a yet further embodiment, the peroxide curable elastomers used herein are EPDM rubbers (ethylene propylene diene monomer (M-class) rubber), a type of synthetic rubber. Suitable EPDM rubbers may be obtained from China National Petroleum Corporation (China) under the product names, Kunlun J-2070; Kunlun J-4045; etc., from Mitsui Chemicals, Inc. (Japan) under the product names, EPT 2060M; EPT4045M; EPTX-4010M; etc., from Dow Chemicals under the trade names, Nordel™ 4570; Nordel™ 5565; etc., from Lanxess under the trade names, Keltan™ 2750; Keltan™ 3960Q; etc., or from ExxonMobile Chemical under the trade names, Vistalon™ V2504; Vistalon™ V5601; etc.

Any peroxide-based curing agent may be used herein. Suitable peroxide-based curing agents include, without limitation, 1,1-bis(tert-buty peroxy)-3,3,5-trimethylcyclohexane; 1,1-di(tert-butylperoxy)cyclohexane; 2,5-di(tert-butylperoxy)-2,5-dimethyl-3-hexyne; 2,5-bis(tert-butylperoxy)-2,5-dimethylhexane; tert-Butylperoxy 2-ethylhexyl carbonate; dicumyl peroxide; benzoyl peroxide; acetylacetone peroxide; methyl isobutyl ketone peroxide; dibenzoyl peroxide; cyclohexanone peroxide; di(4-tert-butylcyclohexyl) peroxydicarbonate; and etc.

In accordance with the present disclosure, the at least one peroxide-based curing agent may be present in the binder material at a level of about 0.1-20 wt %, or about 0.5-10 wt %, or about 1-5 wt %.

Based on the total weight of the ECA composition, the binder material may be present at a level of about 7-60 wt %, or about 15-60 wt %, or about 17-55 wt %.

The conductive particles used herein provide electrical conductivity in the adhesive composition upon circuit connection. The conductive particles may include metal particles, non-metal particles, metal coated particles, and combinations thereof. Suitable metal particles include, without limitation, particles of Au, Ag, Ni, Cu, Al, Sn, Zn, Ti, Sn, Bi, W, Pb, and alloys of two or more thereof. Suitable non-metal particles include, without limitation, carbon nanotube, graphene, polyaniline, polyacetylene, and polypyrrole, and combinations of two or more thereof. The metal coating material used in the metal coated particles may include, without limitation, Au, Ag, Ni, and combinations of two or more thereof. Suitable metal coated particles include, without limitation, Ag-coated glass beads, Ag-coated polystyrene particles, Ag-coated Cu particles, Ni-coated Cu particles, and combinations of two or more thereof. The size of the conductive particles may be determined depending on the pitch of circuits and may be, e.g., about 0.1 to about 50 μm, depending on the intended application.

Based on the total weight of the ECA composition, the conductive particles may be present at a level of about 40-93 wt %, or about 40-85 wt %, or about 45-83 wt %.

The olefinic carboxylic acids used herein have a formula R¹CO₂R², wherein R¹ is hydrocarbyl or substituted hydrocarbyl having 4 or more carbon atoms, and containing one α-olefinic double bond, provided that the double bond is not part of a ring; and R² is hydrogen, hydrocarbyl or substituted hydrocarbyl. Exemplary suitable olefinic carboxylic acids include, without limitation, 4-pentenoic acid; 2-methyl-4-pentenoic acid methyl ester; 2,2-dimethyl-4-pentenoic acid; 5-hexenoic acid; 6-heptenoic acid; 6-heptenoic acid methyl ester; 7-octenoic acid; 8-nonenoic acid; 9-decenoic acid; 10-undecenoic acid; mono-2-(methacryloyloxy)ethyl succinate; methyl 10-undecenoate; 11-dodecenoic acid; 7-oxo-11-dodecenoic acid; 12-tridecanoic acid; and etc.

Based on the total weight of the electrically conductive adhesive composition, the olefinic carboxylic acids may be present at a level of about 0.1-1.5 wt %, or about 0.2-1.5 wt %, or about 0.5-1 wt %.

Further disclosed herein are ECA sheets or tapes formed of the electrically conductive adhesive compositions disclosed.

Further, the ECA compositions or ECA sheets or tapes, as disclosed above may be cured under heat and optional pressure. During the curing process, the peroxide-curable elastomers are crosslinked by the peroxide-based curing agents. Therefore, further disclosed herein are ECA comprising a binder matrix formed of peroxide cured elastomer(s), and conductive particles dispersed in the binder matrix, and olefinic carboxylic acids or derivatives thereof dispersed in the binder matrix.

Yet further disclosed herein are articles comprising the ECA described above. The articles include, without limitation, solar cell modules, light emitting diode (LED) bulb, hand-held devices (such as smart phone), tablet PC, digital camera, laptop, portable wifi server, wearable devices like smart band, wireless telecom infrastructure (WTI), display, and etc.

Yet further disclosed herein are solar cell modules that comprise one or more solar cells and the ECA.

In one embodiment, the ECA are included to electrically connect the surface electrodes of the solar cells with the wiring members (also called ribbons). And the wiring members are included to electrically connect the solar cells in series and/or in parallel and to form conductive paths for extracting the electric power out from the modules.

The solar cells used herein may be any article or material that can convert light into electrical energy. For example, the solar cells used herein include, without limitation, wafer-based solar cells (e.g., c-Si or mc-Si based solar cells) and thin film solar cells (e.g., a-Si, μc-Si, CdTe, copper indium selenide (CIS), copper-indium-gallium selenide (CIGS), light absorbing dyes, or organic semiconductor based solar cells).

The surface electrodes of the solar cells may be made of any suitable materials that can provide electrical conduction. For example, the surface electrodes may be formed by printing (e.g., screen printing or ink-jet printing) conductive paste over the solar cell surfaces. Specific examples of the suitable paste materials include, without limitation, silver paste, silver-containing glass paste, gold paste, carbon paste, nickel paste, aluminum paste, transparent conducting oxide (TCO) (such as indium tin oxide (ITO) or aluminum zinc oxide (AZO).

The wiring members, however, may be formed of any high conductive materials, such as copper, silver, aluminum, gold, nickel, cadmium, and alloys thereof.

The surface electrodes of the solar cells may be in any suitable patterns and the connection between the surface electrodes and the wiring member may be in any suitable forms.

For example, in a wafer-based solar cell module, each solar cell may comprise a front surface electrode and a back surface electrode, wherein the front surface electrode may be comprised of a plurality of parallel conductive fingers and two or more conductive bus bars perpendicular to and connecting the conductive fingers, and wherein the back surface electrode may be comprised of a layer of conductive paste and two or more conductive bus bars. The conductive fingers and the conductive bus bars may be formed of silver paste and the layer of conductive paste comprised in the back surface electrode may be formed of aluminum paste. In such embodiments, the wiring members are connected to the front and back surface electrodes by adhering to the bus bars of the front and back surface electrodes via the ECA disclosed herein.

Or, the front and/or back surface electrodes comprised in the solar cells may be free of bus bars. That is to say, for example, each of the solar cells comprises a front surface electrode that is formed of the plurality of conductive fingers only without bus bars and a back surface electrode that is formed of a layer of conductive paste and two or more conductive bus bars. In such embodiments, the wiring members are connected to the front surface electrode by adhering to the conductive fingers via the electrically conductive adhesives and to the back surface electrode by adhering to the bus bars via the ECA. Or, each of the solar cells comprises a front surface electrode that is formed of the plurality of conductive finger and two or more bus bars and a back surface electrode that is formed of the conductive paste only without the bus bars. In such embodiments, the wiring members are connected to the front surface electrode by adhering to the bus bars via the electrically conductive adhesives and to the back surface electrode by adhering to the conductive paste via the ECA. Or, each of the solar cells comprises a front surface electrode that is formed of the plurality of conductive fingers only without bus bars and a back surface electrode that is formed of the conductive paste only without the bus bars. In such embodiments, the wiring members are connected to the front surface electrode by adhering to the conductive fingers via the ECA and to the back surface electrode by adhering to the conductive paste via the ECA.

In the form of thin film solar cell modules, the opposite surface electrodes are typically formed of transparent TCO layers or metal grids. In certain embodiments, the back surface electrodes may also be formed of metal films, (such as Al, TiN, Zn, Mo, stainless steel). In such embodiments, the wiring members may be connected to the electrodes by adhering to the electrodes via the ECA. In certain embodiments, however, bus bars may be used and connected to each of the electrodes and the wiring members may be connected to the electrodes by adhering to the bus bars via the ECA.

In a further embodiment, the solar cell modules comprise one or more strings of series-connected solar cells arranged in an over-lapping shingle pattern. It is also termed shingled cell modules or dense cell interconnects.

In such embodiments, the series-connected solar cells comprise at least a first solar cell and a second solar cell. Each of the first and second solar cells comprises a front surface electrode and a back surface electrode. The first and second solar cells are positioned with an edge of the back surface of the second solar cell overlapping an edge of the front surface of the first solar cell and a portion of the front surface electrode of the first solar cell is hidden by the second solar cell and bonded to a portion of the back surface electrode of the second solar cell with the ECA disclosed herein to electrically connect the first and second solar cells in series.

In such shingled cell modules, each of the series-connected solar cells may have a rectangular or substantially rectangular shape. The front surface electrode may be comprised of a plurality of parallel conductive fingers and a bus bar perpendicular to and connecting the conductive fingers and positioned adjacent to the edge of one side of the solar cell. The back surface electrode may be comprised of a layer of conductive paste and a bus bar also positioned to the edge of one side of the solar cell and the front and back bus bars are positioned along opposite sides of the solar cells. And it is configured that two adjacent solar cells of the series-connected solar cells are positioned in an overlapping geometry with their sides bearing the bus bars parallel to each other and with the back bus bar of one of the solar cells overlapping and physically and electrically connected to the front bus bar of the other solar cell via the ECA disclosed above. It is also conceivable that either one of both of the front and back bus bars are replaced by a contact pad. Or, either one of both of the front and back bus bars are replaced by two or more discrete contact pads that are arranged along the edge of one side of the solar cells. Or, either one or both of the front and back bus bars are omitted. In those embodiments, the current-collecting functions would be performed, or partially performed, by the ECAs used to bond the adjacent and overlapping solar cells.

Any suitable process may be used to adhere the wiring member(s) to the surface electrode(s) via the electrically conductive adhesives disclosed herein. In one embodiment, the process may include: mixing and dissolving the peroxide curable elastomer(s), the peroxide-based curing agent(s), the conductive particles, the olefinic carboxylic acid or derivative thereof, and other additives in a solvent (such as methyl isobutyl ketone, methyl ethyl ketone, diisobutyl ketone, C-11 ketone, or mixtures thereof); casting the solution over one or both sides of the wiring member(s) followed by drying; and laminating the coated wiring members over the surface electrode(s) of the solar cells. Or, the process may include: mixing and dissolving the peroxide curable elastomer, the peroxide-based curing agent, the conductive particles, the olefinic carboxylic acid or derivative thereof, and other additives in a suitable solvent; casting the solution over the surface electrode(s) of the solar cells followed by drying; and laminating the wiring members over the coated surface of the surface electrode(s). In a further embodiment, the process may include first preparing a pre-formed film or sheet of the ECA composition and then laminating the wiring member(s) over the surface electrode(s) with the pre-formed electrically conductive film or sheet inbetween. And, the pre-formed ECA film or sheet may be prepared by any suitable methods, such as casting (over a release film), extrusion, calendering, etc.

As demonstrated by the examples below, it is found that, the inclusion of olefinic carboxylic acids or derivatives thereof can very much improve the adhesion strength of the peroxide curable elastomer based ECA without reducing its conductivity.

The following Examples and Comparative Examples are provided in order to set forth particular details of one or more embodiments. However, it will be understood that the embodiments are not limited to the particular details described.

### Examples

Material:
FE-1: a vinylidene fluoride/hexafluoropropylene/tetrafluoroethylene terpolymer obtained from DuPont with the trade name Viton®GF200S;
FE-2: a vinylidene fluoride/hexafluoropropylene/tetrafluoroethylene terpolymer obtained from DuPont under the trade name Viton®GBL200;
AEM: an ethylene acrylate dipolymer elastomer obtained from DuPont under the trade name Vamac® DP;
Ag flakes: silver flakes (D50: 3-6 μm) obtained from Kunming Noble Metal Electronic Materials Co., Ltd. (China);
TAIC: triallyl isocyanurate obtained from DuPont under the trade name of Diak™7;
BHT: butylated hydroxytoluene obtained from Sinopharm Chemical Reagent Co., Ltd. (China);
Antioxidant: 4,4′-bis(α,α-dimenthylbenzyl) diphenylamince obtained from Chemtura Corporation (U.S.A.) under the trade name Naugurd™ 445;
MgO: magnesium oxide, obtained from Kyowa Chemical Industry Co., Ltd., (Japan);
Curing Agent: peroxide-based curing agent (1,1-di(t-butylperoxy)-3,3,5-trimethylcyclohexane) obtained from Sinopharm Chemical Reagent Co., Ltd;
Adhesion promoter-1: a bonding agent obtained from Dow Chemical Company under the trade name MEGUM™ 3290-1;
Adhesion promoter-2: γ-glycidylpropyltrimethoxysilane obtained from Sinopharm Chemical Reagent Co., Ltd.;
10-undecenoid acid: obtained from Sigma-Aldrich (U.S.A.);
Mono-2-(Methacryloyloxy)ethyl succinate: obtained from Sigma-Aldrich;
Oleic acid: obtained from Sigma-Aldrich;
Maleic acid: obtained from Sigma-Aldrich;

### Comparative Example CE1-CE6 and Examples E1-E9

In each of the examples, an ECA composition was prepared by first dissolving the elastomer(s), the processing aids, and the curing agent in a MIBK/DIBK solvent (methyl isobutyl ketone/diisobutyl ketone (1:3 by weight)) and then mixing the other constituent materials (e.g., the Ag flakes, adhesion promoters, and optionally acid(s)) in the solution to form an ECA solution.

To determine the volume resistivity of the ECA in each example, the ECA solution as prepared above was blade-casted on an insulating glass slide to form a 30×2 mm strip; dried at 80° C. for 10 min; and cured in a vacuum laminator at about 0.1 MPa and about 155° C. for about 15 min.

The sheet resistance of the cured ECA strips were measured by a four-probe method using a sheet resistivity meter (manufactured by Quatek Co. Ltd. (Taiwan) with the model name QT-70/5601Y) and the thickness of the cured ECA strip was measured using a Dektal XT™ stylus profiler (manufactured by Bruker Corp. (Germany)). The volume resistivity of the cured ECA strips were calculated by the equation below and tabulated in Tables 1 and 2:

ρ(Resistivity)=sheet resistance×thickness×geometry correction=sheet resistance×thickness×1.9475/4.5324

Also, ECA solution as prepared above in each example was casted over the front bus bars of a c-Si solar cell followed by drying at 80° C. for 15 min. Then a Tin coated Cu ribbon (1.2 mm wide) was manually soldered over the ECA strip at 220° C., followed by vacuum lamination at 155° C. and 0.1 MPa for 15 min. The 180° peel strength between the Tin coated Cu ribbon and the front bus bars were determined in accordance with ASTM D903 and tabulated in Tables 1 and 2. Similarly, Tin coated Cu ribbons was bonded over the back bus bars of the back surface of the c-Si cell via the ECA prepared above, and the 180° peeling strength between the Tin coated Cu ribbon and the back bus bars was determined and tabulated in Tables 1 and 2.

As demonstrated by E1-E9, the addition of the olefinic carboxylic acid disclosed herein (e.g., 10-undecenoid acid or mono-2-(methacryloyloxy)ethyl succinate) could improve the adhesion property of the elastomer-based ECA. Also, as shown by CE6, in order to maintain low resistivity, it is preferred to keep the content level of the olefinic carboxylic acid not greater than 1.5 wt %.

TABLE 1

| | | | | | | | | |
|---|---|---|---|---|---|---|---|---|
| CE1 | CE2 | CE3 | CE4 | El | E2 | E3 | E4 | E5 |

Composition

| Elastomer | FE-1 (wt %) | 19.35 | 19.3 | 19.2 | 19.2 | 19.3 | 19.2 | 19.12 | 19.2 | 19.2 |
|---|---|---|---|---|---|---|---|---|---|---|
| | AEM (wt %) | 4.84 | 4.83 | 4.8 | 4.8 | 4.83 | 4.8 | 4.77 | 4.8 | 4.8 |
| Ag flakes (wt %) | | 74 | 73.83 | 73.48 | 73.48 | 73.83 | 73.48 | 73.12 | 73.48 | 73.48 |
| Processing | TAIC (wt %) | 0.34 | 0.34 | 0.34 | 0.34 | 0.34 | 0.34 | 0.34 | 0.34 | 0.34 |
| Aids | BHT (wt %) | 0.025 | 0.025 | 0.025 | 0.025 | 0.025 | 0.025 | 0.025 | 0.025 | 0.025 |
| | Antioxidant (wt %) | 0.025 | 0.025 | 0.025 | 0.025 | 0.025 | 0.025 | 0.025 | 0.025 | 0.025 |
| | MgO (wt %) | 0.46 | 0.45 | 0.45 | 0.45 | 0.45 | 0.45 | 0.45 | 0.45 | 0.45 |
| Curing Agent (wt %) | | 0.48 | 0.48 | 0.48 | 0.48 | 0.48 | 0.48 | 0.48 | 0.48 | 0.48 |
| Adhesion promoter-1 (wt %) | | 0.24 | 0.24 | 0.24 | 0.24 | 0.24 | 0.24 | 0.24 | 0.24 | 0.24 |
| Adhesion promoter-2 (wt %) | | 0.24 | 0.24 | 0.24 | 0.24 | 0.24 | 0.24 | 0.24 | 0.24 | 0.24 |
| Acid | 10-undecenoid acid | — | — | — | — | 0.24 | 0.72 | 1.19 | — | 0.36 |
| | (wt %) | | | | | | | | | |
| | Mono-2- | — | — | — | — | — | — | — | 0.72 | 0.36 |
| | (Methacryloyloxy)ethyl | | | | | | | | | |
| | succinate (wt %) | | | | | | | | | |
| | Oleic acid (wt %) | — | 0.24 | 0.72 | | — | — | — | — | — |
| | Maleic acid (wt %) | — | — | | 0.72 | — | — | — | — | — |

Properties

| | | | | | | | | | |
|---|---|---|---|---|---|---|---|---|---|
| Volume resistivity (ohm-cm) | 5.30E−05 | 9.40E−05 | 1.10E−04 | >2E−3 | 6.20E−05 | 7.10E−05 | 7.50E−05 | 6.40E−05 | 6.90E−05 |
| Peeling strength (F-Bus bar) | 0.83 | 0.88 | 1.3 | nd | 1.1 | 1.5 | 1.6 | 1.1 | 1.5 |
| (N/mm) | | | | | | | | | |
| Peeling strength (B-Bus bar) | 0.67 | 1 | 1.1 | nd | 1 | 1.7 | 1.7 | 1.25 | 1.5 |
| (N/mm) | | | | | | | | | |

TABLE 2

| | | | | | |
|---|---|---|---|---|---|
| CE5 | E6 | E7 | E8 | E9 | CE6 |

Compositions

| Elastomer | FE-2 (wt %) | 19.35 | 19.3 | 19.28 | 19.2 | 19.12 | 19 |
|---|---|---|---|---|---|---|---|
| | AEM (wt %) | 4.84 | 4.83 | 4.82 | 4.8 | 4.77 | 4.74 |
| Ag flakes (wt %) | | 74 | 73.83 | 73.74 | 73.48 | 73.12 | 72.6 |
| Processing | TAIC (wt %) | 0.34 | 0.34 | 0.34 | 0.34 | 0.34 | 0.34 |
| Aids | BHT (wt %) | 0.025 | 0.025 | 0.025 | 0.025 | 0.025 | 0.02 |
| | Antioxidant (wt %) | 0.025 | 0.025 | 0.025 | 0.025 | 0.025 | 0.02 |
| | MgO (wt %) | 0.46 | 0.45 | 0.45 | 0.45 | 0.45 | 0.45 |
| Curing Agent (wt %) | | 0.48 | 0.48 | 0.48 | 0.48 | 0.48 | 0.47 |
| Adhesion Promoter-1 (wt %) | | 0.24 | 0.24 | 0.24 | 0.24 | 0.24 | 0.24 |
| Adhesion promoter-2 (wt %) | | 0.24 | 0.24 | 0.24 | 0.24 | 0.24 | 0.24 |
| Acid | 10-undecenoid acid (wt %) | — | 0.24 | 0.36 | 0.72 | 1.19 | 1.89 |

Properties

| | | | | | | |
|---|---|---|---|---|---|---|
| Volume resistivity (ohm-cm) | 1.90E−04 | 1.60E−04 | 1.70E−04 | 1.90E−04 | 2.80E−04 | 3.70E−04 |
| Peeling strength (F-Bus bar) (N/mm) | 0.92 | 1.8 | 2.1 | 2.1 | 2.6 | nd |
| Peeling strength (B-Bus bar) (N/mm) | 1.35 | 2 | 2 | 2.2 | 2.8 | nd |

nd: not determined

1. An electrically conductive adhesive composition comprising:
a) a binder formed of or comprising at least one peroxide curable elastomer and at least one peroxide-based curing agent;
b) 40-93 wt % of conductive particles dispersed in the binder; and
c) 0.1-1.5 wt % of olefinic carboxylic acid or derivative thereof dispersed in the binder, with the wt % of all components comprised in the composition totaling to 100 wt %, and wherein, the olefinic carboxylic acid has a formula R¹CO₂R², R¹ being hydrocarbyl or substituted hydrocarbyl having 4 or more carbon atoms, and containing one α-olefinic double bond, provided that the double bond is not part of a ring; and R² being hydrogen, hydrocarbyl, or substituted hydrocarbyl.

2. The electrically conductive adhesive composition of claim 1, wherein, the at least one peroxide-based curing agent is present in the binder at a level of 0.1-20 wt % and the at least one peroxide-based curing agent is selected from the group consisting of 1,1-bis(tert-buty peroxy)-3,3,5-trimethylcyclohexane; 1,1-di(tert-butylperoxy)cyclohexane; 2,5-di(tert-butylperoxy)-2,5-dimethyl-3-hexyne; 2,5-bis(tert-butylperoxy)-2,5-dimethylhexane; tert-Butylperoxy 2-ethylhexyl carbonate; dicumyl peroxide; benzoyl peroxide; acetylacetone peroxide; methyl isobutyl ketone peroxide; dibenzoyl peroxide; cyclohexanone peroxide; di(4-tert-butylcyclohexyl) peroxydicarbonate; and combinations of two or more thereof.

3. The electrically conductive adhesive composition of claim 2, wherein, the at least one peroxide curable elastomer is a selected from the group consisting of fluoroelastomers, ethylene/alkyl (meth)acrylate copolymer elastomers, and combinations of two or more thereof.

4. The electrically conductive adhesive composition of claim 2, wherein, the binder is present at a level of 7-60 wt %, based on the total weight of the electrically conductive adhesive composition.

5. The electrically conductive adhesive composition of claim 2, wherein, the conductive particles are present at a level of 40-85 wt % based on the total weight of the electrically conductive adhesive composition, and wherein, the conductive particles are selected from the group consisting of Au, Ag, Ni, Cu, Al, Sn, Zn, Ti, Sn, Bi, W, Pb, and alloys of two or more thereof, or, the conductive particles are Ag flakes.

6. The electrically conductive adhesive composition of claim 2, wherein, the olefinic carboxylic acid or derivative thereof is present at a level of 0.2-1.5 wt %, based on the total weight of the electrically conductive adhesive composition.

7. The electrically conductive adhesive composition of claim 2, wherein, the olefinic carboxylic acid or derivative thereof is selected from the group consisting of 4-pentenoic acid; 2-methyl-4-pentenoic acid methyl ester; 2,2-dimethyl-4-pentenoic acid; 5-hexenoic acid; 6-heptenoic acid; 6-heptenoic acid methyl ester; 7-octenoic acid; 8-nonenoic acid; 9-decenoic acid; 10-undecenoic acid; mono-2-(methacryloyloxy)ethyl succinate; methyl 10-undecenoate; 11-dodecenoic acid; 7-oxo-11-dodecenoic acid; 12-tridecanoic acid; and combinations of two or more thereof.

8. A film or sheet formed of the electrically conductive adhesive composition according claim 1.

9. An electrically conductive adhesive prepared from the electrically conductive adhesive composition of claim 1, wherein, the at least peroxide curable elastomer is cured by the at least one peroxide-based curing agent.

10. A solar cell module comprising at least one solar cell and at least one wiring member, wherein, the at least one solar cell has at least one surface electrode and the at least one wiring member is connected to the at least one surface electrode via the electrically conductive adhesive of claim 9.

11. The solar cell module of claim 10, wherein the at least one solar cell has a front surface electrode and a back surface electrode, and wherein there are one or more front wiring members connected to the front surface electrode via the electrically conductive adhesive and one or more back wiring members connected to the back surface electrode via the electrically conductive adhesive.

12. The solar cell module of claim 11, wherein the at least one solar cell is a wafer-based solar cell.

13. The solar cell module of claim 11, wherein the at least one solar cell is a thin film solar cell.

14. A solar cell module comprising one or more strings of solar cells, wherein each string of solar cells comprise at least a first solar cell and a second solar cell, with i) each of the first and second solar cells comprising a front surface electrode and a back surface electrode; ii) the first and second solar cells being positioned with an edge of the back surface of the second solar cell overlapping an edge of the front surface of the first solar cell; and iii) a portion of the front surface electrode of the first solar cell being hidden by the second solar cell and bonded to a portion of the back surface electrode of the second solar cell with the electrically conductive adhesive of claim 9 to electrically connect the first and second solar cells in series.

15. The electrically conductive adhesive composition of claim 1, wherein, the at least one peroxide-based curing agent is present in the binder at a level of 0.5-10 wt % and the at least one peroxide-based curing agent is selected from the group consisting of 1,1-bis(tert-buty peroxy)-3,3,5-trimethylcyclohexane; 1,1-di(tert-butylperoxy)cyclohexane; 2,5-di(tert-butylperoxy)-2,5-dimethyl-3-hexyne; 2,5-bis(tert-butylperoxy)-2,5-dimethylhexane; tert-Butylperoxy 2-ethylhexyl carbonate; dicumyl peroxide; benzoyl peroxide; acetylacetone peroxide; methyl isobutyl ketone peroxide; dibenzoyl peroxide; cyclohexanone peroxide; di(4-tert-butylcyclohexyl) peroxydicarbonate; and combinations of two or more thereof.

16. The electrically conductive adhesive composition of claim 2, wherein, the binder is present at a level of 17-55 wt %, based on the total weight of the electrically conductive adhesive composition.

17. The electrically conductive adhesive composition of claim 2, wherein, the olefinic carboxylic acid or derivative thereof is present at a level of 0.5-1 wt %, based on the total weight of the electrically conductive adhesive composition.
